(19) United States
(12) Patent Application Publication
(10) Pub. No.: US 2025/0162200 A1
(43) Pub. Date: May 22, 2025

(54) FIXING JIG AND SUBSTRATE PROCESSING APPARATUS INCLUDING THE SAME

(71) Applicant: SAMSUNG DISPLAY CO., LTD., YONGIN-SI (KR)

(72) Inventors: SEONGYUN LEE, Yongin-si (KR); JUNG-BIN LIM, Yongin-si (KR); HWANWOONG LEE, Yongin-si (KR)

(21) Appl. No.: 18/948,139

(22) Filed: Nov. 14, 2024

(30) Foreign Application Priority Data
Nov. 22, 2023 (KR) 10-2023-0162886

(51) Int. Cl. B28D 5/00

(52) U.S. Cl. CPC B28D 5/0082

(57) ABSTRACT

A fixing jig includes a body portion, an insertion portion extending from the body portion along a first direction and a cover portion extending from the body portion along the first direction, spaced apart from the insertion portion along a second direction intersecting the first direction. The cover portion includes a first surface and a second surface opposite to the first surface. The second surface of the cover portion faces the insertion portion, and second surface of the cover portion includes a groove.

### CROSS-REFERENCE TO RELATED APPLICATION

This application claims priority under 35 U.S.C. § 119 to Korean Patent Application No. 10-2023-0162886, filed on Nov. 22, 2023, in the Korean Intellectual Property Office, the content of which is incorporated by reference herein in its entirely.

### 1. TECHNICAL FIELD

The present disclosure relates generally to a fixing jig. More particularly, the present disclosure relates to a fixing jig and a substrate processing apparatus including the same.

### 2. DISCUSSION OF THE RELATED ART

A substrate processing apparatus used in production of a semiconductor, a display device, a solar cell, etc. performs a heat treatment process on a predetermined thin film deposited on a substrate, such as a silicon wafer or glass. The heat treatment process includes, for example, crystallization and phase change. For example, the substrate processing apparatus performs a heat treatment process to form a low temperature poly crystallization silicon (LTPS) device that forms a thin film transistor using polycrystalline silicon on a substrate. In addition, the substrate processing apparatus performs a heat treatment process to form and cure a polyimide on a substrate to form a flexible substrate. To perform such a heat treatment process, the substrate processing apparatus includes a support portion for supporting a substrate during the process and a heating portion for applying heat to the substrate.

During the heat treatment process, the support portion often experiences displacement from its original position due to the heat and vibrations generated.

### SUMMARY

Embodiments provide a fixing jig for fixing a support portion of a substrate processing apparatus.

Embodiments provide a substrate processing apparatus including the fixing jig.

A fixing jig according to an embodiment of the present disclosure includes a body portion, an insertion portion extending from the body portion along a first direction and a cover portion extending from the body portion along the first direction, spaced apart from the insertion portion along a second direction intersecting the first direction. The cover portion includes a first surface and a second surface opposite to the first surface. The second surface of the cover portion faces the insertion portion, and second surface of the cover portion includes a groove.

A substrate processing apparatus according to an embodiment of the present disclosure includes a support portion disposed inside a chamber, defining a space for processing a substrate, the support portion supporting the substrate, a heating portion disposed under the support portion and configured to heat the substrate and a fixing jig contacting each of the support portion and the heating portion. The fixing jig includes a body portion, an insertion portion extending from the body portion and a cover portion extending from the body portion, spaced apart from the insertion portion. The cover portion includes a first surface and a second surface opposite to the first surface. The second surface of the cover portion faces the insertion portion. The second surface of the cover portion includes a groove.

A fixing jig according to an embodiment of the present disclosure includes a body portion, an insertion portion extending upwardly from the body portion and a cover portion extending vertically from the body portion. The cover portion includes a horizontal groove that faces the insertion portion.

### BRIEF DESCRIPTION OF THE DRAWINGS

Example embodiments will be more clearly understood from the following detailed description in conjunction with the accompanying drawings.

FIG. 1 is a cross-sectional view illustrating a substrate processing apparatus according to an embodiment of the present disclosure.

FIG. 2 is an enlarged cross-sectional view of area ‘A’ of FIG. 1.

FIG. 3 is a cross-sectional view illustrating a heating portion included in the substrate processing apparatus of FIG. 1.

FIG. 4 is an enlarged perspective view of area ‘B’ of FIG. 2.

FIG. 5 is a perspective view illustrating a fixing jig according to an embodiment of the present disclosure.

FIG. 6 is a cross-sectional view illustrating the fixing jig of FIG. 5.

FIG. 7 is a perspective view illustrating the fixing jig of FIG. 5 coupled to the substrate processing apparatus.

### DETAILED DESCRIPTION OF THE EMBODIMENTS

Hereinafter, embodiments of the present disclosure will be described in detail with reference to the accompanying drawings. To the extent that an element has not been described in detail, it may be assumed that the element is at least similar to corresponding elements that have been described in previous figures.

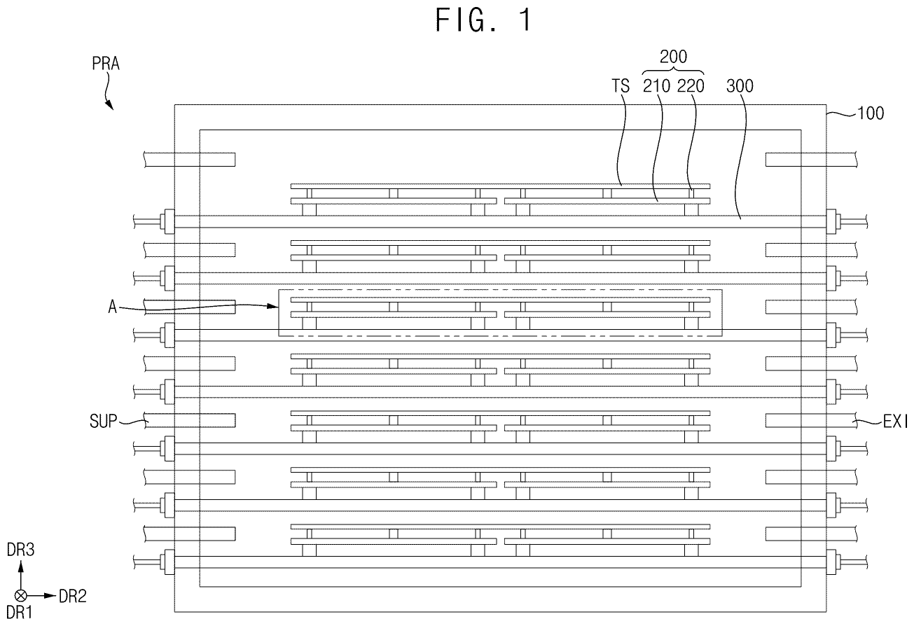

FIG. 1 is a cross-sectional view illustrating a substrate processing apparatus according to an embodiment of the present disclosure.

In this specification, a plane may be defined by a first direction DR1 and a second direction DR2 intersecting the first direction DR1. For example, the first direction DR1 and the second direction DR2 may be perpendicular to each other. A direction normal to the plane may be a third direction DR3. For example, the third direction DR3 may be perpendicular to each of the first direction DR1 and the second direction DR2.

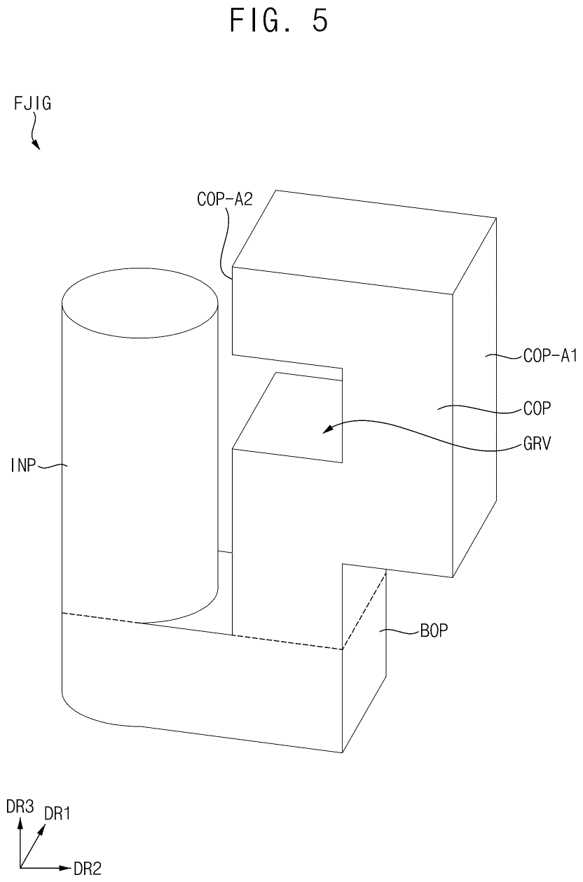

Referring to FIG. 1, a substrate processing apparatus PRA according to an embodiment of the present disclosure may include a chamber 100, a support portion 200, a heating portion 300, a gas supply portion SUP, a gas exhaust portion EXI, and a fixing jig FJIG (refer to FIG. 5).

The chamber 100 may form a space where a substrate TS undergoes processing procedures. For example, the substrate TS may be a substrate used in a display device, a semiconductor substrate, a solar cell substrate, etc. However, the present disclosure is not necessarily limited thereto. In an embodiment, the substrate TS may include a flexible material. The flexible material may refer to a material that is flexible and may be easily bent, folded, or rolled. For example, the substrate TS may include ultrathin type glass or plastic.

In an embodiment, the substrate processing apparatus PRA may perform a heat treatment process on the substrate TS. However, the present disclosure is not necessarily limited thereto, and the substrate processing apparatus PRA may perform various processes such as a deposition process, an etching process, etc.

A gate may be formed on a side wall of the chamber 100. The gate may serve as a passage for the substrate TS to move into an inside of the chamber 100 and an outside of the chamber 100. The substrate TS may be transferred into the chamber 100 through the gate using a substrate loading apparatus such as a transfer arm. The chamber 100 may have a cuboidal shape, but the present disclosure is not necessarily limited thereto.

One side surface of the chamber 100 may be connected to the gas supply portion SUP. The gas supply portion SUP may be connected to a space configured for the processing of the substrate TS. For example, the gas supply portion SUP may penetrate the one side surface of the chamber 100 and may protrude toward an inner side surface of the chamber 100. The gas supply portion SUP may spray a process gas from the one side surface of the chamber 100 toward an upper surface of the substrate TS.

The other side surface, which is disposed opposite to the one side surface of the chamber 100, may be connected to the gas exhaust portion EXI. The gas exhaust portion EXI may be connected to the space for processing the substrate TS. For example, the gas exhaust portion EXI may penetrate the other side surface of the chamber 100 and protrude toward an inner side surface of the chamber 100. The gas exhaust portion EXI may face the gas supply portion SUP. The gas exhaust portion EXI may be connected to a vacuum pump. By driving the vacuum pump, the gas exhaust portion EXI may suck in the process gas remaining inside the chamber 100.

The support portion 200 may be disposed inside the chamber 100. The substrate TS may be loaded on the support portion 200. For example, the support portion 200 may support the substrate TS transferred into the chamber 100. The support portion 200 may include a support ladder portion 210 and a first support portion 220.

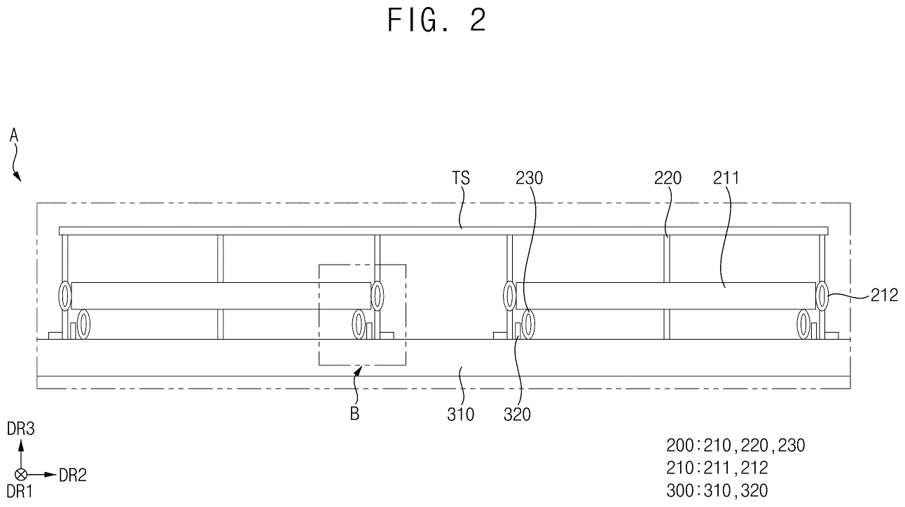

The support ladder portion 210 may include first support ladder portions (211 (refer to FIG. 2) and second support ladder portions 212 (refer to FIG. 2). The support ladder portion 210 may be arranged in a ladder shape. For example, each of the first support ladder portions 211 may extend along the second direction DR2, and the first support ladder portions 211 may be spaced apart from each other along the first direction DR1. Each of the second support ladder portions 212 may extend along the first direction DR1, and the second support ladder portions 212 may be spaced apart from each other along the second direction DR2.

The first support portion 220 may protrude from the support ladder portion 210 toward the substrate TS. For example, the first support portion 220 may protrude from the support ladder portion 210 along the third direction DR3. The first support portion 220 may support the substrate TS. For example, the first support portion 220 may protrude upward from the support ladder portion 210 and may directly contact a lower surface of the substrate TS.

The heating portion 300 may extend along the second direction DR2. The heating portion 300 may extend from the one side surface of the chamber 100 to the other side surface of the chamber 100. The heating portion 300 may be disposed under the support portion 200. The heating portion 300 may heat the substrate TS supported by the support portion 200. Heat emitted from the heating portion 300 may be transferred to the substrate TS through the support portion 200. In addition, the heating portion 300 may be disposed under the support portion 200 and support the support portion 200.

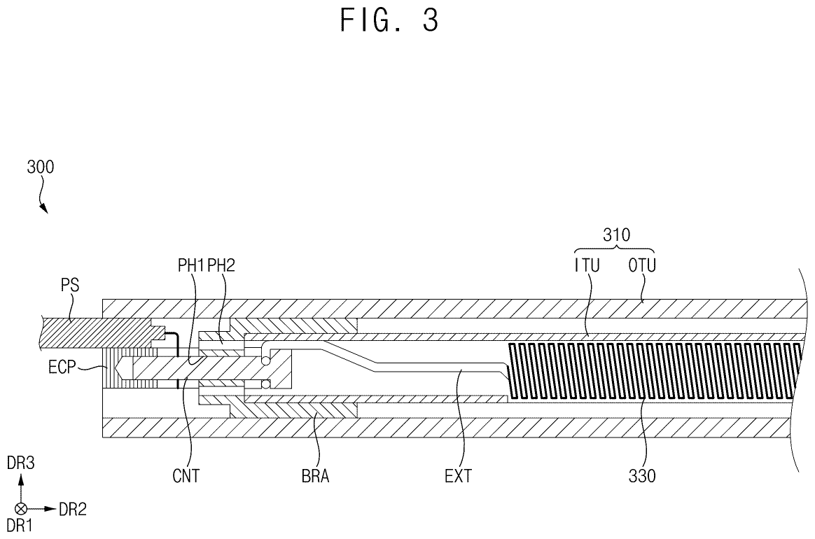

The heating portion 300 may include a heater portion which emits heat, a heater tube portion 310 which covers the heater portion 330, and a protrusion 320 protruding from the heater tube portion toward the support portion 200. A detailed description thereof will be provided below with reference to FIGS. 2 and 3.

The fixing jig FJIG (refer to FIG. 5) may contact each of the support portion 200 and the heating portion 300. The fixing jig FJIG may prevent the support portion 200 from deviating from its original position due to vibration. A detailed description thereof will be provided below with reference to FIGS. 5, 6, and 7.

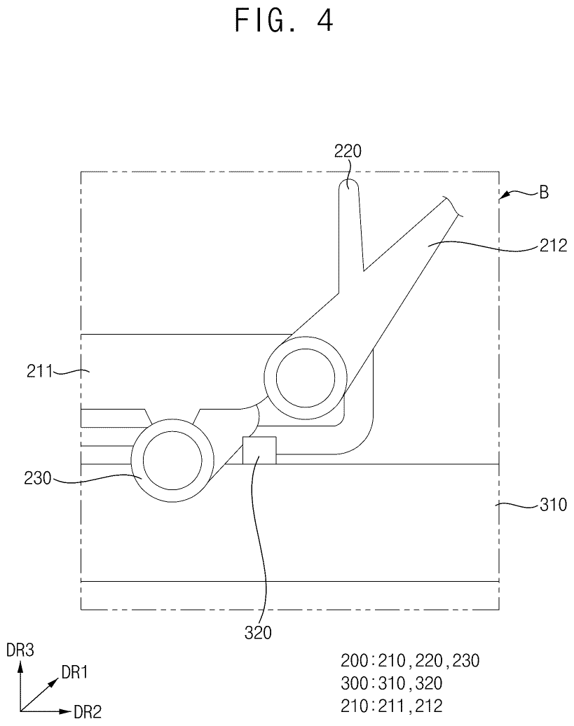

FIG. 2 is an enlarged cross-sectional view of area ‘A’ of FIG. 1. FIG. 3 is a cross-sectional view illustrating a heating portion included in the substrate processing apparatus of FIG. 1. FIG. 4 is an enlarged perspective view of area ‘B’ of FIG. 2.

Referring to FIGS. 2, 3, and 4, the substrate processing apparatus PRA according to an embodiment of the present disclosure may include the support portion 200 and the heating portion 300. The support portion 200 may include the support ladder portion 210, the first support portion 220, and a second support portion 230.

The first support portion 220 may protrude from the support ladder portion 210 toward the substrate TS. For example, the first support portion 220 may protrude from each of the first support ladder portions 211 and/or each of the second support ladder portions 212 toward the substrate TS. That is, the first support portion 220 may protrude upward from the first support ladder portions 211 and/or upward from the second support ladder portions 212.

The support portion 200 may include a plurality of first support portions 220 repeatedly disposed along the second direction DR2 on the support ladder portion 210. In addition, the support portion 200 may include the plurality of first support portions 220 repeatedly disposed along the first direction DR1 on the support ladder portion 210. The plurality of first support portions 220 may support the substrate TS by directly contacting the lower surface of the substrate TS.

The second support portion 230 may be disposed between the support ladder portion 210 and the heating portion 300. For example, the second support portion 230 may be disposed between the support ladder portion 210 and a heater tube portion 310. The second support portion 230 may be disposed on the heater tube portion 310 and may directly contact a lower surface of the support ladder portion 210. Accordingly, the second support portion 230 may support the support ladder portion 210. For example, the second support portion 230 may be integrally formed with the support ladder portion 210, but the present disclosure is not necessarily limited thereto. In an embodiment, the second support portion 230 may have a hollow cylindrical shape. Accordingly, the second support portion 230 may provide a space into which an insertion portion INP (refer to FIG. 5) of the fixing jig FJIG may be inserted.

As illustrated in FIGS. 2 and 3, the heating portion 300 may include the heater tube portion 310, a protrusion 320, a heater portion 330, an extension portion EXT, a terminal portion CNT, a bracket BRA, and a cap portion ECP.

The heater tube portion 310 may include a first tube ITU and a second tube OTU. The first tube ITU may be disposed inside the second tube OTU and may at least partially cover the heater portion 330. As used herein, the phrase “at least partially covering” may mean that the first element covers some or all of the second element. The first tube ITU may include a transparent material or an opaque material. In an embodiment, the first tube ITU may have a cylindrical shape with a predetermined diameter. For example, the first tube ITU may be referred to as an inner tube.

The second tube OTU may at least partially cover the first tube ITU. The second tube OTU may directly contact the support portion 200. The second tube OTU may include a transparent material or an opaque material. In an embodiment, the second tube OTU may have a cylindrical shape with a predetermined diameter. A diameter of the second tube OTU may be greater than a diameter of the first tube ITU. For example, the second tube OTU may be referred to as an outer tube.

In an embodiment, each of the first tube ITU and the second tube OUT may include glass or quartz.

The protrusion 320 may protrude from the heater tube portion 310 toward the support portion 200. Specifically, the protrusion 320 may protrude from an upper side of the heater tube portion 310 toward a bottom surface of the support portion 200. The protrusion 320 may be spaced apart from the support portion 200. In other words, the protrusion 320 may not directly contact the support portion 200. In an embodiment, the protrusion 320 may include glass or quartz. The protrusion 320 may include the same material as the heater tube portion 310. The protrusion 320 may be integrally formed with the heater tube portion 310. For example, the protrusion 320 may have a cylindrical shape. The protrusion 320 may be surrounded by a cover portion COP (refer to FIG. 5) of the fixing jig FJIG.

The heater portion 330 may be covered by the heater tube portion 310. For example, the heater portion 330 may include a coil structure having a predetermined pitch and may be inserted into the first tube ITU. A diameter of the heater portion 330 and a pitch of the heater portion 330 may be configured in various ways in consideration of an amount of heat generated. Here, the diameter of the heater portion 330 may refer to a length of the heater portion 330 along the third direction DR3.

The heater portion 330 may extend along a longitudinal direction of the heater tube portion 310 (i.e., the second direction DR2). A length of the heater portion 330 may be configured in various ways in consideration of a heat generation area. Here, the length of the heater portion 330 may refer to a length of the heater portion 330 along the second direction DR2.

The extension portion EXT may be disposed between the heater portion 330 and the terminal portion CNT. The extension portion EXT may extend along the second direction DR2. One end of the extension portion EXT may be connected to the heater portion 330, and the other end of the extension portion EXT may be connected to the terminal portion CNT. The extension portion EXT may transmit power provided by an external terminal PS to the heater portion 330.

The terminal portion CNT may be disposed between the external terminal PS and the extension portion EXT. The terminal portion CNT may be connected with the first tube ITU. The terminal portion CNT may include a head portion connected to the extension portion EXT and a rod portion which penetrates the bracket BRA and is connected to the external terminal PS. The terminal portion CNT may include a metal, an alloy, a metal nitride, a conductive metal oxide, a transparent conductive material, etc. For example, the terminal portion CNT may include a conductive material with high electrical conductivity, such as copper (Cu) or aluminum (Al). These may be used alone or in combination with each other.

The bracket BRA may be disposed between the first tube ITU and the second tube OTU. The bracket BRA may support and fix the first tube ITU within the second tube OTU. A first through hole PH1 and a second through hole PH2 may be formed in the bracket BRA. The first through hole PH1 may be formed for through installation of the terminal portion CNT. For example, the rod portion of the terminal portion CNT may penetrate the bracket BRA through the first through hole PH1. The second through hole PH2 may dissipate heat emitted by the heater portion 330 from the inside of the first tube ITU to the outside of the first tube ITU. Accordingly, excessive heat generation of the heater portion 330 may be prevented.

The cap portion ECP may be disposed at both opposing ends of the second tube OTU. The cap portion ECP may block the terminal portion CNT from being exposed to the outside of the second tube OTU.

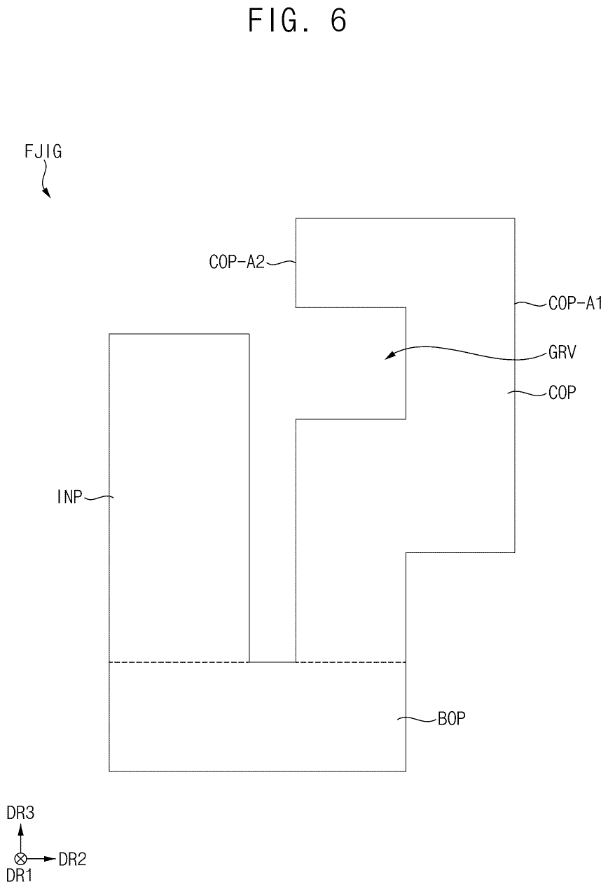

FIG. 5 is a perspective view illustrating a fixing jig according to an embodiment of the present disclosure. FIG. 6 is a cross-sectional view illustrating the fixing jig of FIG. 5.

Referring to FIGS. 5 and 6, a fixing jig FJIG according to an embodiment of the present disclosure may include a body portion BOP, an insertion portion INP, and a cover portion COP.

The body portion BOP may include a flat surface. The body portion BOP may support the insertion portion INP and the cover portion COP. In an embodiment, the body portion BOP may include glass or quartz. For example, the body portion BOP may have a cuboidal shape, but the present disclosure is not necessarily limited thereto.

The insertion portion INP may extend from the body portion BOP along the third direction DR3. In an embodiment, the insertion portion INP may include glass or quartz. In an embodiment, the insertion portion INP may have a cylindrical shape. However, the present disclosure is not necessarily limited thereto, and the insertion portion INP may have a shape corresponding to a shape of the second support portion 230 which is illustrated in FIG. 4.

The cover portion COP may extend from the body portion BOP along the third direction DR3. The cover portion COP may be spaced apart from the insertion portion INP along the second direction DR2. The cover portion COP may include a first surface COP-A1 and a second surface COP-A2 which is facing the opposite direction from the first surface COP-A1. For example, the second surface COP-A2 may face the insertion portion INP. For example, the first surface COP-A1 may be oriented towards the second direction DR2, and the second surface COP-A2 may be oriented towards direction opposite to the second direction DR2. In an embodiment, the cover portion COP may include glass or quartz.

In an embodiment, with respect to the body portion BOP, an upper surface of the cover portion COP may be located at a higher level than an upper surface of the insertion portion INP. In other words, with respect to the body portion BOP, a height of the upper surface of the cover portion COP which is measured along the third direction DR3 may be greater than a height of the upper surface of the insertion portion INP which is measured along the third direction DR3.

The second surface COP-A2 of the cover portion COP may include a groove GRV. The groove GRV may refer to a portion of the second surface COP-A2 recessed toward the first surface COP-A1. In an embodiment, the groove GRV may have a square, semi-circular, or semi-elliptical cross-sectional shape.

In an embodiment, a portion of the cover portion COP may have a U-shaped cross-sectional shape. For example, the cover portion COP may include the groove GRV in which a portion of the second surface COP-A2 is recessed toward the first surface COP-A1, and the groove GRV may not penetrate the cover portion COP in a thickness direction (i.e., the second direction DR2) of the cover portion COP. However, the present disclosure is not necessarily limited thereto, and the cover portion COP may have various shapes which may surround the protrusion 320 illustrated in FIG. 4.

In an embodiment, the body portion BOP, the insertion portion INP, and the cover portion COP may include the same material. For example, the body portion BOP, the insertion portion INP, and the cover portion COP may include quartz. In this case, the body portion BOP, the insertion portion INP, and the cover portion COP may be integrally formed. However, the present disclosure is not necessarily limited thereto.

The body portion BOP, the insertion portion INP, and the cover portion COP may include the same material as the support portion 200 and the heater tube portion 310 which are illustrated in FIG. 4. For example, each of the body portion BOP, the insertion portion INP, the cover portion COP, the support portion 200, and the heater tube portion 310 may include quartz.

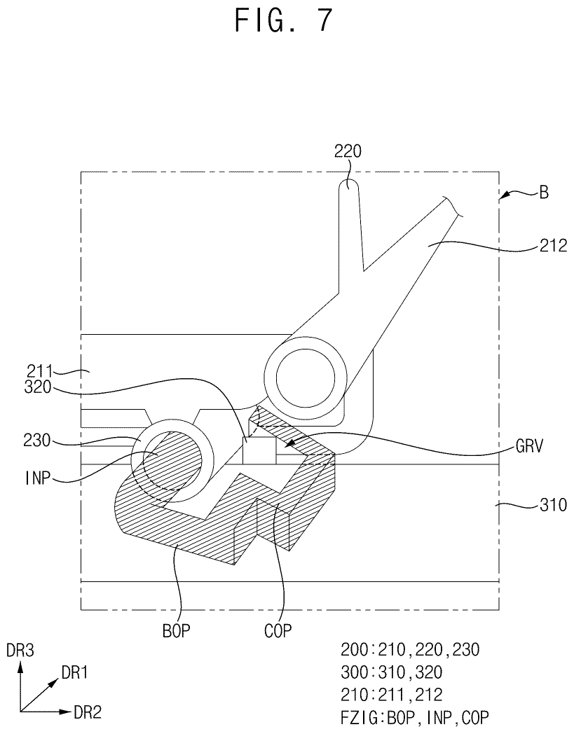

FIG. 7 is a perspective view illustrating the fixing jig of FIG. 5 coupled to the substrate processing apparatus.

Referring to FIGS. 5 and 7, the fixing jig FJIG may contact each of the support portion 200 and the heating portion 300. For example, the fixing jig FJIG may contact each of the second support portion 230 and the protrusion 320.

The second support portion 230 may be disposed between the support ladder portion 210 and the heater tube portion 310. The second support portion 230 may be disposed on the heater tube portion 310 and may directly contact a lower surface of the support ladder portion 210. Accordingly, the second support portion 230 may support the support ladder portion 210. The second support portion 230 may be integrally formed with the support ladder portion 210. For example, the second support portion 230 may be integrally formed with the first support ladder portion 211. In an embodiment, the second support portion 230 may have a hollow cylindrical shape.

The insertion portion INP may have a shape corresponding to a shape of the second support portion 230. In an embodiment, the insertion portion INP may have a cylindrical shape. Accordingly, the insertion portion INP may be inserted into the second support portion 230. A diameter of the insertion portion INP may be provided considering a diameter of the second support portion 230. For example, the diameter of the insertion portion INP may be about 15 millimeters.

The protrusion 320 may protrude from the heater tube portion 310 toward the support portion 200. The protrusion 320 may be integrally formed with the heater tube portion 310. For example, the protrusion 320 may have a cylindrical shape.

The second surface of the cover portion COP may include the groove GRV. The groove GRV may refer to a portion of the second surface recessed toward the first surface. In an embodiment, the groove GRV may have a square, semi-circular, or semi-elliptical cross-sectional shape. The cover portion COP may surround the protrusion 320. Accordingly, the protrusion 320 may be located inside the groove GRV.

The support portion 200 may deviate from its original position due to heat and vibration generated in the process of heat treating the substrate TS. For example, as the support ladder portion 210 deviates from its original position, the first support portion 220, which protrudes from the support ladder portion 210 toward the substrate TS, may also deviate from its original position. In this case, the substrate TS might not support by the first support portion 220, and the substrate TS may be impacted and damaged.

In order to suppress a problem of the substrate TS being damaged by impact, the fixing jig FJIG according to an embodiment of the present disclosure may include the insertion portion INP, which inserts into the interior of the second support portion 230, and the cover portion which at least partially surrounds the protrusion 320. As the cover portion COP at least partially surrounds the protrusion 320 and the insertion portion INP is inserted into the interior of the second support portion 230, the support portion 200 may be fixed and maintain its original position even though heat and vibration are generated in the process. Accordingly, the problem of damage to the substrate TS that may occur when the support 200 deviates from its original position may be suppressed.

The insertion portion INP may be inserted into the second support portion 230 with a predetermined gap from the second support portion 230. In addition, the cover portion COP may at least partially surround the protrusion 320 with a predetermined gap from the protrusion 320. Accordingly, compared to a method of fixing the support portion 200 through welding, damage to the support portion 200 due to thermal expansion and thermal contraction may be relatively reduced.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A fixing jig, comprising:
a body portion;
an insertion portion extending from the body portion along a first direction; and
a cover portion extending from the body portion along the first direction, spaced apart from the insertion portion along a second direction intersecting the first direction,
wherein the cover portion includes a first surface and a second surface opposite to the first surface,
wherein the second surface of the cover portion faces the insertion portion, and
wherein the second surface of the cover portion includes a groove.

2. The fixing jig of claim 1, wherein the insertion portion has a cylindrical shape.

3. The fixing jig of claim 1, wherein a portion of the cover portion has a U-shaped cross-section.

4. The fixing jig of claim 1, wherein the groove has a cross-sectional shape that is square, semi-circular, or semi-elliptical.

5. The fixing jig of claim 1, wherein with respect to the body portion, an upper surface of the cover portion is disposed at a higher level than an upper surface of the insertion portion.

6. The fixing jig of claim 1, wherein each of the body portion, the insertion portion, and the cover portion includes glass and/or quartz.

7. The fixing jig of claim 1, wherein the body portion, the insertion portion, and the cover portion include a same material.

8. A substrate processing apparatus, comprising:
a support portion disposed inside a chamber, defining a space for processing a substrate, the support portion supporting the substrate;
a heating portion disposed under the support portion and configured to heat the substrate; and
a fixing jig contacting each of the support portion and the heating portion,
wherein the fixing jig comprises:
a body portion;
an insertion portion extending from the body portion; and
a cover portion extending from the body portion, spaced apart from the insertion portion,
wherein the cover portion includes a first surface and a second surface opposite to the first surface,
wherein the second surface of the cover portion faces the insertion portion, and
wherein the second surface of the cover portion includes a groove.

9. The apparatus of claim 8, wherein the support portion includes:
a support ladder portion;
a first support portion protruding from the support ladder portion toward the substrate, and supporting the substrate; and
a second support portion disposed between the support ladder portion and the heating portion, and supporting the support ladder portion.

10. The apparatus of claim 9, wherein the second support portion has a hollow cylindrical shape, and
wherein the insertion portion is inserted into the second support portion.

11. The apparatus of claim 8, wherein the heating portion includes:
a heater portion configured to emit heat;
a heater tube portion at least partially covering the heater portion; and
a protrusion protruding from the heater tube portion toward the support portion.

12. The apparatus of claim 11, wherein the cover portion surrounds the protrusion, and
wherein the protrusion is disposed inside the groove.

13. The apparatus of claim 8, wherein the insertion portion has a cylindrical shape.

14. The apparatus of claim 8, wherein a portion of the cover portion has a U-shaped cross-section.

15. The apparatus of claim 8, wherein the groove has a cross-sectional shape that is square, semi-circular, or semi-elliptical.

16. The apparatus of claim 8, wherein with respect to the body portion, an upper surface of the cover portion is disposed at a higher level than an upper surface of the insertion portion.

17. The apparatus of claim 8, wherein each of the body portion, the insertion portion, and the cover portion includes glass and/or quartz.

18. The apparatus of claim 8, wherein the body portion, the insertion portion, and the cover portion include a same material.

19. A fixing jig, comprising:
a body portion;
an insertion portion extending upwardly from the body portion; and
a cover portion extending vertically from the body portion,
wherein the cover portion includes a horizontal groove that faces the insertion portion.
